(19) United States
(12) Patent Application Publication
(10) Pub. No.: US 2023/0335667 A1
(43) Pub. Date: Oct. 19, 2023

(54) SYSTEM FOR TREATING A PHOTOVOLTAIC MODULE WITH A VIEW TO INCREASING ITS EFFICIENCY

(71) Applicant: COMMISSARIAT A L'ENERGIE ATOMIQUE ET AUX ENERGIES ALTERNATIVES, Paris (FR)

(72) Inventors: Pedro JERONIMO, Grenoble cedex 09 (FR); Jean-Sébastien CARON, Grenoble cedex 09 (FR); Jordi VEIRMAN, Grenoble cedex 09 (FR)

(73) Assignee: COMMISSARIAT A L'ENERGIE ATOMIQUE ET AUX ENERGIES ALTERNATIVES, Paris (FR)

(21) Appl. No.: 18/300,883

(22) Filed: Apr. 14, 2023

(30) Foreign Application Priority Data
Apr. 15, 2022 (FR) 22 03531

(51) Int. Cl. H01L 31/18; H02S 50/15

(52) U.S. Cl. CPC H01L 31/186; H02S 50/15

(57) ABSTRACT

A system for treating a surface to be treated of a photovoltaic installation formed from one photovoltaic module or from a plurality of juxtaposed photovoltaic modules, the system including an emission source for emitting electromagnetic radiation, the emission source being configured to emit electromagnetic radiation, the system including: a device for moving the emission source, a control unit configured to control the emission source with a view to emitting the electromagnetic radiation for a determined exposure time with a given irradiance towards at least one portion of the surface to be treated, the control unit being configured to control the moving device so as to move the emission source with respect to the surface to be treated until the entire photovoltaic surface has been scanned.

### TECHNICAL FIELD OF THE INVENTION

The present invention relates to a system for treating at least one photovoltaic module with a view to increasing its efficiency.

### PRIOR ART

Silicon heterojunction (SHJ) photovoltaic cells are known to see their energy conversion efficiency improve by about 0.3% absolute under the combined action of light and heat. Thus, it is now common to carry out a light-soaking treatment to improve stacks, notably those intended to form SHJ photovoltaic cells, in order to increase their conversion efficiency.

Document WO2013/001440 describes one example of a process for treating SHJ photovoltaic cells comprising a substrate made of n-doped crystalline silicon. In this treatment process, the photovoltaic cell is subjected to a light flux of irradiance higher than or equal to 500 W/m² for a time of about 10 hours, while being heated to a temperature comprised between 20° C. and 200° C.

Patent application FR3099294A1 describes a process for treating what is referred to as a precursor stack of a heterojunction photovoltaic cell. This process is implemented at the end of manufacture and mainly consists in exposing said stack to intense electromagnetic radiation (irradiance higher than 200 kW/m²) for a relative short time (about ten seconds). By virtue of this brief but intense exposure to radiation, the cell is improved and its efficiency in operation increased.

However, the efficiency of a module once installed in a solar park tends to decrease with time and there is no apt way of once again increasing this efficiency after a few months/years of use.

In addition, certain already installed modules may never have had their cells light-soaked. It would therefore be desirable to be able to provide a way of treating these modules, after installation.

The aim of the invention is therefore to provide a system allowing the efficiency of a photovoltaic module to be improved, even after a few months/years of use, or when it has never undergone a light-soaking treatment.

### SUMMARY OF THE INVENTION

This aim is achieved by means of a system for treating a surface to be treated of a photovoltaic installation formed from one photovoltaic module or from a plurality of juxtaposed photovoltaic modules, said system comprising an emission source for emitting electromagnetic radiation, said emission source being configured to emit electromagnetic radiation, said system comprising:
means for moving said emission source,
a control unit configured to control said emission source with a view to emitting said electromagnetic radiation for a determined exposure time with a given irradiance towards at least one portion of the surface to be treated,
the control unit being configured to control the moving means so as to move said emission source with respect to said surface to be treated until the entire photovoltaic surface has been scanned.

According to one particularity, the system comprises means for determining a degree of opacity of the photovoltaic installation in said at least one portion of the surface to be treated.

According to another particularity, the means for determining opacity comprise:
means for emitting a light beam towards said at least one portion of the surface to be treated and means for receiving a light flux reflected by said at least one portion of the surface to be treated,
a module, executed by said control unit, for computing the degree of opacity on the basis of data received from the receiving means.

According to another particularity, the system comprises means for cooling the module and for regulating the temperature of the module to a determined value during the exposure of said at least one portion of the surface to be treated to said electromagnetic radiation.

According to another particularity, the system comprises means for determining dimensions of the surface to be treated of the photovoltaic installation.

According to one particular embodiment, the control unit is configured to execute a sequence of treatment of said surface to be treated, comprising the following steps:
a)determining the degree of opacity of the photovoltaic installation in a first portion of the surface to be treated;
b)determining the irradiance and the exposure time to be applied to said first portion of the surface to be treated given the determined degree of opacity;
c) controlling the emission source to irradiate said first portion of the surface;
d)controlling the means for moving the emission source to place the latter facing a second portion of the surface to be treated, said second portion being distinct from the first portion;
e)executing steps a) to d), applied to the second portion of the surface to be treated.

According to another particular embodiment, the control unit is configured to execute a sequence of treatment of said surface to be treated, comprising the following steps:
a)scanning the surface of the photovoltaic module by moving the emission source at a set speed;
b)determining the degree of opacity of the module in each portion of the surface to be treated;
c)determining the irradiance and the exposure time to be applied to each portion of the surface to be treated given the determined degree of opacity;
d)controlling the emission source to irradiate each portion of the surface to be treated;
e)provided that the determined degree of opacity remains constant, keeping the speed of movement of the emission source at the set speed;
f) when the variation in the degree of opacity exceeds a threshold value, determining a new irradiance and a new exposure time to be applied, and determining a new set speed to be applied to the emission source.

According to one particularity, the moving means comprise at least one rail fastened to an edge of the photovoltaic installation and the system comprises an arm supporting said emission source, said arm being configured to slide along said rail.

According to another particularity, the system comprises means for cleaning the surface to be treated.

According to another particularity, the irradiance is comprised between 1 and 100 kW/m².

According to another particularity, the irradiance is comprised between 1 kW/m² and 10 kW/m².

According to another particularity, the exposure time is comprised between 1 second and 30 minutes.

According to another particularity, the temperature of the photovoltaic installation is regulated to a value comprised between 100° C. and 250° C.

### BRIEF DESCRIPTION OF THE FIGURES

Other features and advantages will become apparent from the following detailed description, which is given with reference to the appended drawings, in which:

FIG. 1 shows, in perspective and schematically, the structure of a photovoltaic module;

FIG. 2 shows a side view of the structure of a photovoltaic module;

FIG. 3 illustrates the operating principle of the invention;

FIG. 4 schematically shows the functional architecture of the system of the invention;

FIG. 5 shows one example of embodiment of the internal face of the system of the invention;

FIGS. 6A and 6B show one example of embodiment of the solution for determining the degree of opacity of a photovoltaic module;

FIG. 7 shows one example of an algorithm for determining the degree of opacity of a photovoltaic module;

FIGS. 8A and 8B show two examples of embodiment of the system of the invention;

FIGS. 9A and 9B show two examples of an algorithm for operating the system of the invention.

### DETAILED DESCRIPTION OF AT LEAST ONE EMBODIMENT

The invention consists in artificially illuminating a photovoltaic module M already installed in a solar park, in order to improve its current efficiency.

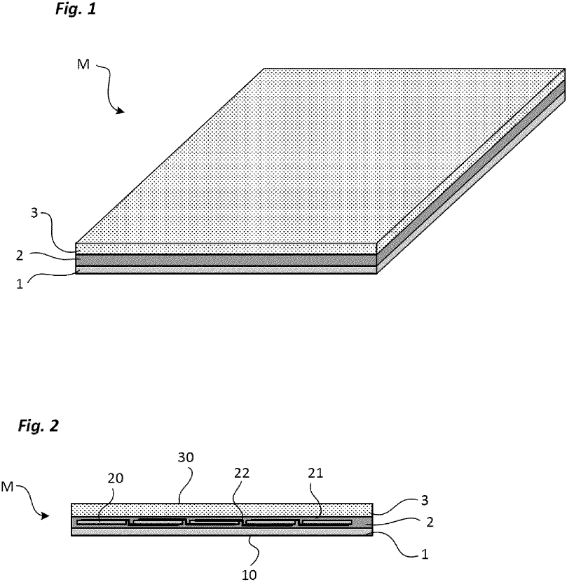

With reference to FIG. 1 and to FIG. 2, as known, a photovoltaic module M comprises a plurality of layers that are superposed on and joined to one another:
a first layer 1 (commonly called the back sheet) forming a first protective element on the back side 10; this first layer 1 is conventionally made of a polymer;
a second layer 2, which is called the intermediate layer as it is intermediate between the first layer 1 and the third layer 3 (described below), and which is joined on one side to the first layer and on the other side to the third layer; this intermediate layer 2 comprises the photovoltaic cells 20, the electrical interconnects 22 and an encapsulating jacket 21 that is arranged around the photovoltaic cells;
a third layer 3 forming a second protective element on the front side 30; this third layer 3 is conventionally made of glass but it may optionally be formed from a transparent polymer; the third layer forms the planar external surface of the module, which surface is intended to be exposed to radiation.

For the sake of legibility in the appended figures, the various layers of the module have not been shown to scale. By way of example, the first layer 1 may have a thickness of a few hundred µm (for example about 350 µm), the second layer 2 may have a thickness that may be as much as 1 mm and the third layer 3 may have a thickness of about 3 to 4 mm.

The first layer 1 may notably perform a function providing impermeability to gases and water, a function providing electrical protection/insulation and a function providing mechanical protection. This first layer 1 may be made based on a fluoropolymer. It may be a question of polyvinyl fluoride (PVF), for example as sold under the name TEDLAR (registered trademark of the company DuPont (registered trademark)).

Non-limitingly, the first layer 1 may itself be composed of a stack of a plurality of strata: one stratum of PVF, one stratum of PET (polyethylene terephthalate), one stratum of PVF.

In the intermediate layer 2, the encapsulating jacket 21 is conventionally made of a polymer such as EVA (ethylene vinyl acetate), forming a material to which may adhere the first layer 1 on one side and the third layer 3 on the other side, and allowing the three layers to be joined together. The three layers may be joined to each other by hot rolling, such that the first layer and the third layer adhere to the material of the encapsulating jacket, thus forming an integral stack.

In the intermediate layer 2, the photovoltaic cells 20 are connected to one another, in series/parallel, forming a plurality of strings of cells. Electrical interconnects 22, for example made of copper, make it possible to electrically connect the cells 20 in each string.

The photovoltaic module M may comprise a frame (not shown), for example a frame made of aluminium, arranged on the periphery of the stack to increase the rigidity of the module M.

As a general rule, the solar park comprises a plurality of photovoltaic modules that are aligned and juxtaposed, and that are advantageously all identical.

In the rest of the description, the system of the invention is described with respect to use on a single photovoltaic module. However, it must be understood that it may be used successively on all of the photovoltaic modules of the solar park.

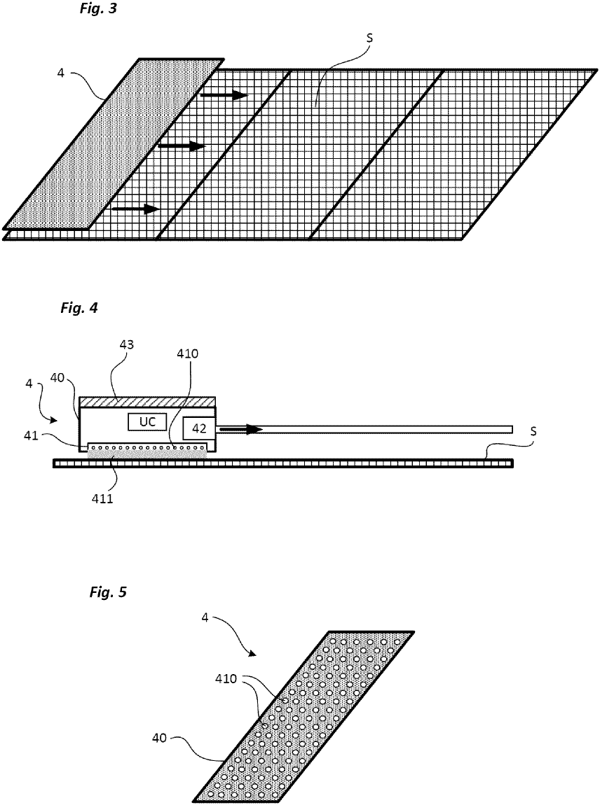

In the rest of the description, and as illustrated in FIG. 3, reference is made to the surface S to be treated by the system 4, which may correspond to the surface of one photovoltaic module or to a surface formed by the juxtaposition of a plurality of photovoltaic modules. As indicated above, the surface S may be formed by a partition made of glass or of a transparent polymer, placed above the photovoltaic cells 20 to be treated.

With reference to FIG. 4, the system 4 of the invention comprises a body 40 intended to be positioned facing the surface to be treated.

The system comprises a control unit UC comprising computing and control means. It may for example be a question of a programmable logic controller comprising a plurality of input/output modules.

The system of the invention comprises an emission source 41 for emitting electromagnetic radiation. This emission source 41 is advantageously composed of a plurality of light-emitting diodes 410 that are integrated into said body of the system. As shown in FIG. 5, it may comprise a number of rows of light-emitting diodes integrated into a carrier of the body 40 of the system.

The emission source 41 forms a region of illumination 411, defined by the total area that the source 41 is capable of treating when it is active. This region of illumination 411 for example corresponds to at least the entire region occupied by the light-emitting diodes that form the emission source 41.

When the body 40 of the system 4 is positioned facing the surface S to be treated, the light-emitting diodes 410 of the source 41 are positioned so as to be able to expose the surface S to radiation sufficient for obtaining the improving effect. Non-limitingly, a plurality of light-emitting diodes 410 are positioned so as to emit in a main direction that is normal to the surface S to be treated.

The radiation is applied for a determined treatment time (called the exposure time T), which may vary depending on the irradiance E and the wavelength of the emitted radiation. It will be recalled that irradiance E, or radiant flux per unit area, is the power of the electromagnetic radiation received per unit area, this unit area being oriented perpendicular to the direction of the emitted electromagnetic radiation.

The electromagnetic radiation may be monochromatic (a single wavelength) or polychromatic (a plurality of components of different wavelengths). More precisely, the radiation may be emitted at at least one wavelength comprised between 400 nm and 1100 nm, and preferably at a wavelength comprised between 800 nm and 1000 nm.

Non-limitingly, depending on the mode of operation, the electromagnetic radiation may be emitted with an irradiance comprised between 1 kW/m² and 100 kW/m² for a time comprised between 5 seconds and 30 minutes.

By way of example, the electromagnetic radiation may be emitted with an irradiance E higher than or equal to 8 kW/m² and for a time shorter than or equal to 4 minutes.

The electromagnetic radiation may also be emitted with an irradiance E higher than or equal to 50 kW/m² and for a time shorter than or equal to 15 seconds.

During the emission of the radiation, the temperature of the module M is advantageously kept at the stablest possible value, which value is for example between 100° C. and 250° C. It will be noted that it is important for the treatment applied by the module not to lead to exceedance of the minimum value of the maximum temperatures theoretically acceptable to the solder joints present in the module and to the encapsulating material, as otherwise the module risks being damaged.

The system may be equipped with means for managing the temperature of the surface to be treated:
one or more temperature sensors arranged to measure the temperature of the treated surface S;
cooling means 43 that are controlled to regulate surface temperature;
   these cooling means may comprise one fan or a plurality of fans and/or be a solution that cools using a coolant; these cooling means 43 are advantageously integrated into the body 40 of the system 4 of the invention;
a software module for regulating temperature, which module is executed by the control unit UC and loaded to generate the commands to be sent to the cooling means to regulate the temperature to the desired value.

The system of the invention is intended to treat the surface of each photovoltaic module of the solar park.

It should be noted that if the surface S to be treated is smaller in size than the region of illumination delivered by the system, the system 4 will be able to treat the entire surface S in one go. In this situation, the activation of the emission source 41 may be partial and tailored to the surface S to be treated.

If the surface S to be treated is larger than the size of the region of illumination 411 delivered by the system 4, the system 4 will be moved with respect to the surface S so as to treat in turn every region of the surface until the entire surface has been covered.

The system 4 advantageously comprises means for determining the area of the surface of each module and the total area of the surface S to be treated, and means for comparing same with its region of illumination 411. The control unit UC thus determines the operating mode to be used to treat the entirety of the surface S.

The system 4 thus comprises means 42 for moving the system 4, so as to move the emission source 41 and its region of illumination 411 with respect to each region of the surface S to be treated.

The system 4 advantageously comprises means for determining the degree of opacity DO (expressed in % - at 0% the surface of the module is opaque and at 100% the surface of the module is transparent) of each photovoltaic module. Since the photovoltaic modules M are located on the exterior, they are exposed to particles, such as dust, sand and dirt, increasing their degree of opacity with respect to that obtained when they left the factory.

The means for determining the degree of opacity DO for example comprise a unit for emitting light signals, infrared signals for example, towards at least one region of the surface of the photovoltaic module, and a unit for receiving signals reflected by the surface of the photovoltaic module. These determining means are advantageously integrated into the system of the invention. The emitting unit and the receiving unit may be integrated into the emission source 41 of the system.

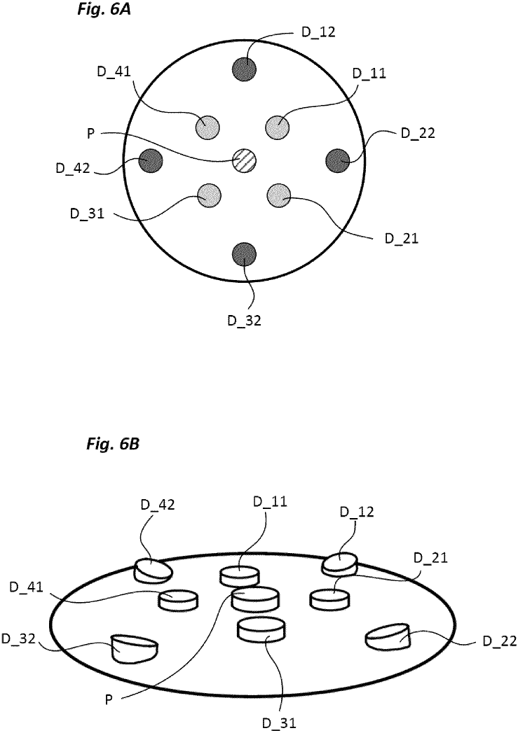

The receiving unit then sends data to the control unit UC, which executes a module for determining the degree of opacity of the photovoltaic module in the region scanned. By way of example, with reference to FIG. 6A and to FIG. 6B, the emitting unit may comprise a plurality of light-emitting diodes, which for example are eight in number, arranged symmetrically around a phototransistor P forming the receiving unit. A first set of four light-emitting diodes D_11, D_21, D_31, D_41 arranged in a square may be placed around the phototransistor P, and be oriented to emit in a direction normal to the surface of the panel, and a second set of four light-emitting diodes D_12, D_22, D_32, D_42 may be placed outside the first set, each thereof being oriented and inclined to emit in a direction at 20° to the surface of the module. The two sets of light-emitting diodes thus form concentric circles located around the phototransistor P. Of course, other arrangements could be imagined.

These units may be integrated directly into the matrix array of light-emitting diodes of the emission source 41. They will be activated while the emission source 41 is inactive.

Depending on the determined degree of opacity DO (in %), the control unit UC may adjust the irradiance E and the exposure time T to be applied to the treated region.

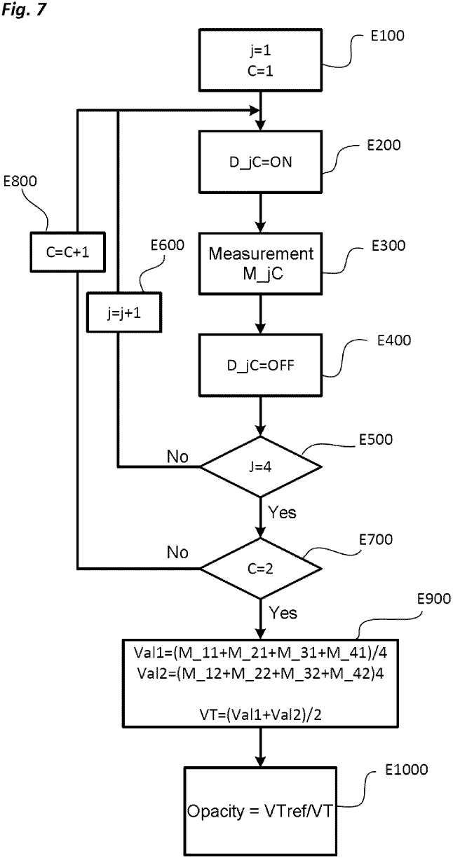

FIG. 7 shows one example of an algorithm for determining the degree of opacity DO of a photovoltaic module, based on the emitting unit made up of eight light-emitting diodes described above, and on the phototransistor P, these being positioned facing the photovoltaic module to be characterized. As shown in FIGS. 6A and 6B, the emitting unit for example comprises two circles (referenced C - indexed 1 or 2) and four light-emitting diodes per circle (each light-emitting diode has an index j, with j ranging from 1 to 4 for each circle C).

In this algorithm, the steps are as follows:
an initializing first step E100 with j=1 and C=1;
a second step E200 in which the first light-emitting diode (referenced D_jC) of the first circle is turned on;
in the third step E300, a first measurement M_jC of the light flux received by the phototransistor P is taken - each measurement is expressed in percent and therefore corresponds to the ratio between the emitted signal and the received signal;
in the fourth step E400, the first light-emitting diode of the first circle is turned off;
this measurement principle is reproduced for each other light-emitting diode of the first circle, up to j = 4 steps E500 and E600;
the same principle is then reproduced for the second circle (C=2) of light-emitting diodes steps E700 and E800;
when all the measurements M_jC have been obtained for every light-emitting diode of the two circles, an average value is determined for the first circle and an average value is determined for the second circle, then an average VT is determined from the two average values step E900;
next, the degree of opacity is determined by applying the relationship Opacity = VTref/VT, VTref corresponding to a pre-established reference value, for example one measured in the factory on a black body step E1000.

Considering the case where the area of the surface S to be treated is larger than the region of illumination 411 of the system, two solutions may be implemented.

In a first solution, the control unit UC determines the degree of opacity DO of a first region of the surface S to be treated then computes the irradiance E to be applied to this first region and the exposure time T given this degree of opacity DO. The control unit UC then controls the emission source 41 so as to apply these parameters to this first region to be treated. Once this first region has been treated, the control unit UC controls the moving means 42 to move the source 41 to a second region of the surface S to be treated and reproduces the same steps. The system 4 thus operates discontinuously, each region of the surface S being treated in turn, the degree of opacity DO and the applied illumination being determined in succession for each region. The speed of movement of the system 4 is thus zero during the treatment and becomes non-zero when the system is moved from a first region of the surface S to be treated to a second region distinct from the first region.

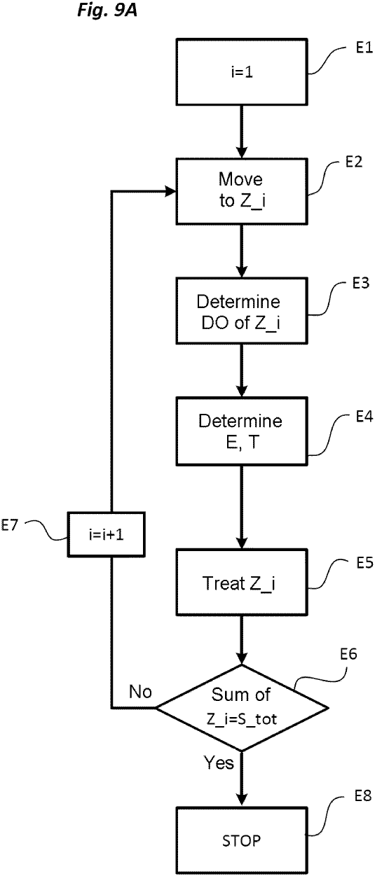

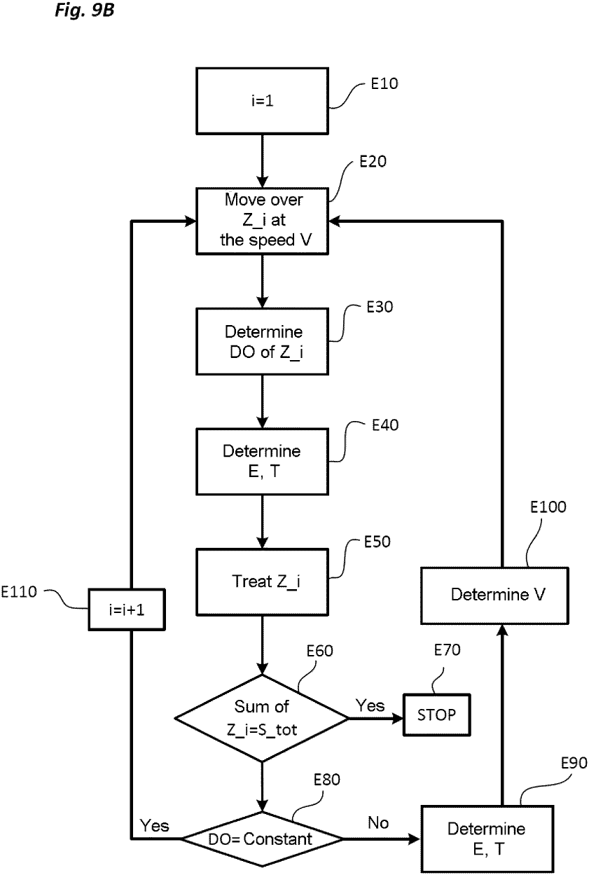

With reference to FIG. 9A, the principle of discontinuous operation could be as follows:
E1: the system 4 is initialized for a first region of the surface (i=1);
E2: the system is positioned above the first region Z_1;
E3: for this first region, the control unit determines the degree of opacity DO;
E4: depending on the determined degree of opacity DO, the control unit determines the irradiance E to be applied and the exposure time T;
E5: the control unit commands treatment of the region Z_1;
E6 + E7: provided that the sum of the Z_i is lower than S_tot, the system moves to a new region to be treated, with i=i+1; S_tot corresponds to the total area to be treated;
E8: when the sum of the Z_i is equal to S_tot, the system stops.

In a second solution, the system 4 may be made to function continuously such that the control unit UC executes a regulation loop via which it continuously determines a speed of movement to be applied to the emission source 41 to subject each region of the surface S to the determined irradiance corresponding to its degree of opacity DO. The speed of movement of the emission source 41 is thus updated in real time and regulated depending on the degree of opacity DO of each region of the surface that is treated and scanned by the system 4. By way of example, with reference to FIG. 9B, the principle of continuous operation could be as follows:
E10: the system is initialized for a first region of the surface (i=1);
E20: the system moves over the region Z_1 at the speed V;
E30: for this first region Z_1, the control unit determines the degree of opacity DO;
E40: depending on the determined degree of opacity, the control unit determines the irradiance E to be applied and the exposure time T;
E50: the control unit treats the region Z_1;
E60 + E110: provided that the sum of the Z_i is lower than S_tot, the system moves and the region to be treated may be modified, with i=i+1 (see below); S_tot corresponds to the total area to be treated;
E70: when the sum of the Z_i is equal to S_tot, the system stops;
E80: provided that the degree of opacity DO remains constant, the system moves to a new region to be treated at the speed V;
E90: when the measured degree of opacity DO changes, the control unit determines a new irradiance E and a new exposure time T; it may be decided that the degree of opacity DO has changed when its variation exceeds a threshold value;
E100: the control unit may modify the speed V of the system to take these modifications into account; specifically, to take the change in opacity into account, it may modify the applied irradiance and/or the exposure time (by varying the speed of movement of the system).

It should be noted that the emission source 41 always remains positioned at an identical distance from the surface S to be treated. Since the latter is planar, the emission source 41 therefore advantageously makes a rectilinear movement in a direction parallel to the surface to be treated.

According to one particular embodiment, the moving means 42 may comprise wheels, which for example are positioned directly on the surface S to be treated, and an electric motor that is controlled to drive said wheels.

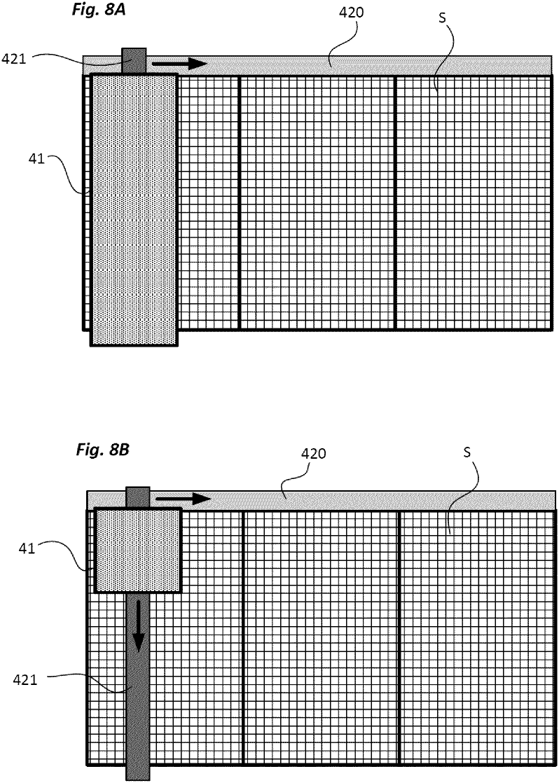

According to another particular embodiment illustrated in FIG. 8A and FIG. 8B, the moving means 42 may comprise a rail 420 fastened to one edge of a photovoltaic module or of a plurality of juxtaposed photovoltaic modules and along which may slide an arm 421 of the system thus bearing the emission source 41. With reference to FIG. 8B, the arm 421 may itself form a guideway along which the emission source 41 taking carriage form may slide. In this way, the source is able to be moved along the two axes (X and Y) parallel to the surface of the panel. Means for moving heightwise (along the axis Z) could also be provided, with a view to adjusting the distance between the emission source 41 and the surface S to be treated.

Any other solution for mounting the system could be provided.

Various improvements may be made to the system 4, notably:
cleaning means, such as a brush or the like, may be securely fastened to the moving system and tasked with cleaning the surface S to be treated as it moves;
communicating means, controlled by the control unit UC, may be provided and used to send data during the operation of the system, such as temperature, speed of movement, position, irradiance, etc.

1. A system for treating a surface to be treated of a photovoltaic installation formed from one photovoltaic module or from a plurality of juxtaposed photovoltaic modules, said system comprising an emission source for emitting electromagnetic radiation, said emission source being configured to emit electromagnetic radiation, wherein said system comprises:
a moving device for moving said emission source
a control unit configured to control said emission source with a view to emitting said electromagnetic radiation for a determined exposure time with a given irradiance towards at least one portion of the surface to be treated,
the control unit being configured to control the moving device so as to move said emission source with respect to said surface to be treated until the entire photovoltaic surface has been scanned.

2. The system according to claim 1, wherein the system comprises a device for determining a degree of opacity of the photovoltaic installation in said at least one portion of the surface to be treated.

3. The system according to claim 2, wherein the device for determining opacity comprise:
a device for emitting a light beam towards said at least one portion of the surface to be treated and a receiving device for receiving a light flux reflected by said at least one portion of the surface to be treated,
a module, executed by said control unit, for computing a degree of opacity on the basis of data received from the receiving device.

4. The system according to claim 1, wherein the system comprises a device for cooling the module and for regulating the temperature of the module to a determined value during the exposure of said at least one portion of the surface to be treated to said electromagnetic radiation.

5. The system according to claim 1, wherein the system comprises a device for determining dimensions of the surface to be treated of the photovoltaic installation.

6. The system according to claim 1, wherein the control unit is configured to execute a sequence of treatment of said surface to be treated, comprising the following steps:
a. determining the degree of opacity of the photovoltaic installation in a first portion of the surface to be treated;
b. determining the irradiance and the exposure time to be applied to said first portion of the surface to be treated given the determined degree of opacity;
c. controlling the emission source to irradiate said first portion of the surface;
d. controlling the moving device for moving the emission source to place the latter facing a second portion of the surface to be treated, said second portion being distinct from the first portion;
e. executing steps a) to d), applied to the second portion of the surface to be treated.

7. The system according to claim 1, wherein the control unit is configured to execute a sequence of treatment of said surface to be treated, comprising the following steps:
a. scanning the surface of the photovoltaic module by moving the emission source at a set speed;
b. determining the degree of opacity of the module in each portion of the surface to be treated;
c. determining the irradiance and the exposure time to be applied to each portion of the surface to be treated given the determined degree of opacity;
d. controlling the emission source to irradiate each portion of the surface to be treated;
e. provided that the determined degree of opacity remains constant, keeping the speed of movement of the emission source at the set speed;
f. when the variation in the degree of opacity exceeds a threshold value, determining a new irradiance and a new exposure time to be applied, and determining a new set speed to be applied to the emission source.

8. The system according to claim 1, wherein the moving device comprise at least one rail fastened to an edge of the photovoltaic installation and wherein the system comprises an arm supporting said emission source said arm being configured to slide along said rail.

9. The system according to claim 1, wherein the system comprises a device for cleaning the surface to be treated.

10. The system according to claim 1, wherein the irradiance is comprised between 1 and 100 kW/m².

11. The system according to claim 10, wherein the irradiance is comprised between 1 kW/m² and 10 kW/m².

12. The system according to claim 1, wherein the exposure time is comprised between 1 s and 30 minutes.

13. The system according to claim 1, wherein the temperature of the installation is regulated to a value comprised between 100° C. and 250° C.
